(19) United States
(12) Patent Application Publication
(10) Pub. No.: US 2025/0185271 A1
(43) Pub. Date: Jun. 5, 2025

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/602,879

(22) Filed: Mar. 12, 2024

(30) Foreign Application Priority Data
Nov. 30, 2023 (CN) 202311629320.9

(51) Int. Cl. H01L 29/778; H01L 29/06; H01L 29/20

(52) U.S. Cl. CPC H10D 30/475; H10D 62/125; H10D 62/8503

(57) ABSTRACT

A semiconductor structure includes a substrate, a buffer layer, a first channel layer, an etching mask layer, a first barrier layer, a second channel layer and a second barrier layer that are stacked sequentially. The etching mask layer includes a plurality of strip-shaped structures, a strip-shaped trench is formed between two adjacent strip-shaped structures in the plurality of strip-shaped structures, an extending direction of the strip-shaped trench is a first direction, the strip-shaped trench penetrates through the etching mask layer and partially penetrates through the first channel layer, the first barrier layer is conformally disposed in the strip-shaped trench and on the etching mask layer, and the first barrier layer includes a second trench corresponding to the strip-shaped trench. The technical solutions of the present disclosure may improve a linearity of a device.

### CROSS-REFERENCE TO RELATED APPLICATIONS

This present application claims priority to Chinese Patent Application No. 202311629320.9, filed on Nov. 30, 2023, which is hereby incorporated by reference in its entirety.

### TECHNICAL FIELD

The present application relates to the field of semiconductor technologies, and in particular, to a semiconductor structure and a manufacturing method for the semiconductor structure.

### BACKGROUND

A High Electron Mobility Transistor (HEMT) is one of field effect transistors, which has a heterostructure formed by using two materials having different energy gaps, and a strong two-Dimensional Electron Gas (2DEG) exists in the heterostructure. The high electron mobility transistor can operate at a high frequency, and therefore it is widely used in mobile phones, satellite televisions and radars.

With respect to a single-channel heterostructure, a multi-channel heterostructure exhibits greater advantages. However, a high electron mobility transistor with a multi-channel heterostructure currently has a short transconductance stabilization period and a poor linearity, and therefore, how to improve transconductance stability and linearity is an urgent problem to be solved by a person skilled in the art.

### SUMMARY

In view of this, embodiments of the present disclosure provide a semiconductor structure and a manufacturing method therefor to improve a linearity of a high electron mobility transistor with a multi-channel heterostructure.

According to an aspect of the present disclosure, an embodiment of the present disclosure provides a semiconductor structure, which includes:
a substrate, a buffer layer, a first channel layer, an etching mask layer, a first barrier layer, a second channel layer and a second barrier layer that are stacked sequentially,
where the etching mask layer includes a plurality of strip-shaped structures, a strip-shaped trench is formed between two adjacent strip-shaped structures in the plurality of strip-shaped structures, an extension direction of the strip-shaped trench is a first direction, the strip-shaped trench penetrates through the etching mask layer and partially penetrates through the first channel layer, the first barrier layer is conformally disposed in the strip-shaped trench and on the etching mask layer, and the first barrier layer includes a second trench corresponding to the strip-shaped trench.

As an alternative embodiment, a band gap width of the first barrier layer is greater than a band gap width of the etching mask layer, and the band gap width of the etching mask layer is greater than a band gap width of the first channel layer.

As an alternative embodiment, a material of the first barrier layer includes AlN, a material of the etching mask layer includes AlGaN, and a material of the first channel layer includes GaN.

As an alternative embodiment, an Al component of at least one strip-shaped structure in the plurality of strip-shaped structures is different from an Al component of a remaining strip-shaped structure in the plurality of strip-shaped structures.

As an alternative embodiment, a surface, away from the first barrier layer, of the second channel layer is a plane.

As an alternative embodiment, the second channel layer is conformally disposed on the first barrier layer, and the second channel layer includes a third trench corresponding to the second trench.

As an alternative embodiment, the second barrier layer is conformally disposed on the second channel layer, and the second barrier layer includes a fourth trench corresponding to the third trench.

As an alternative embodiment, in a plane perpendicular to the first direction, a cross section of the strip-shaped trench is rectangular, trapezoidal, V-shaped, or bowl-shaped.

As an alternative embodiment, a plurality of strip-shaped trenches are formed between the plurality of strip-shaped structures, and an aspect ratio of at least one strip-shaped trench in the plurality of strip-shaped trenches is different from an aspect ratio of a remaining strip-shaped trench in the plurality of strip-shaped trenches.

As an alternative embodiment, a change trend of an aspect ratio of the plurality of strip-shaped trenches includes any one of the following change trends:
a depth of the plurality of strip-shaped trenches is constant and a width of the plurality of strip-shaped trenches changes;
a depth of the plurality of strip-shaped trenches changes and a width of the plurality of strip-shaped trenches is constant;
a depth and a width of the plurality of strip-shaped trenches change in a same proportion; and
a depth and a width of the plurality of strip-shaped trenches change in inverse proportions.

As an alternative embodiment, the semiconductor structure further includes:
a source and a drain, located on the second barrier layer, where a direction of the source pointing to the drain is parallel to the first direction;
a gate, located on the second barrier layer and between the source and the drain; and
a dielectric layer, located on a side, close to the second barrier layer, of the gate.

As an alternative embodiment, the second channel layer, the second barrier layer, the dielectric layer and the gate are conformally disposed on the first barrier layer in sequence, and the gate has a fifth trench corresponding to the second trench.

As an alternative embodiment, the semiconductor structure further includes:
an anode and a cathode, located on the buffer layer and located on two sides of the first channel layer, the etching mask layer, the first barrier layer, the second channel layer and the second barrier layer, where a direction of the anode pointing to the cathode is parallel to the first direction.

According to another aspect of the present disclosure, an embodiment of the present disclosure provides a manufacturing method for a semiconductor structure, which includes:
sequentially stacking a buffer layer, a first channel layer, and an etching mask layer including a plurality of strip-shaped structures on a substrate;
etching the first channel layer exposed by the etching mask layer, where an etching depth is less than a thickness of the first channel layer to form a plurality of strip-shaped trenches, and an extension direction of each strip-shaped trench in the plurality of strip-shaped trenches is a first direction;
conformally disposing a first barrier layer in the strip-shaped trench and on the etching mask layer, where the first barrier layer includes a second trench corresponding to the strip-shaped trench;
disposing a second channel layer on the first barrier layer; and
disposing a second barrier layer on the second channel layer.

As an alternative embodiment, a surface, away from the first barrier layer, of the second channel layer is a plane.

As an alternative embodiment, the second channel layer is conformally disposed on the first barrier layer, and the second channel layer includes a third trench corresponding to the second trench.

As an alternative embodiment, the second barrier layer is conformally disposed on the second channel layer, and the second barrier layer includes a fourth trench corresponding to the third trench.

As an alternative embodiment, in a plane perpendicular to the first direction, a cross section of the strip-shaped trench is rectangular, trapezoidal, V-shaped, or bowl-shaped.

As an alternative embodiment, an aspect ratio of at least one strip-shaped trench in the plurality of strip-shaped trenches is different from an aspect ratio of a remaining strip-shaped trench in the plurality of strip-shaped trenches.

### BRIEF DESCRIPTION OF THE DRAWINGS

FIG. 1 is a schematic structural diagram of a semiconductor structure according to an embodiment of the present disclosure.

FIG. 2a to FIG. 2c are schematic structural diagrams of semiconductor structures according to some embodiments of the present disclosure.

FIG. 3a to FIG. 3d are schematic structural diagrams of semiconductor structures according to some embodiments of the present disclosure.

FIG. 4a to FIG. 4d are schematic structural diagrams of semiconductor structures according to some embodiments of the present disclosure.

FIG. 5 is a schematic structural diagram of a semiconductor structure according to an embodiment of the present disclosure.

FIG. 6 is a flowchart of a manufacturing method for a semiconductor structure according to an embodiment of the present disclosure.

FIG. 7 to FIG. 12 are schematic structural diagrams of intermediate structures corresponding to a process for manufacturing a semiconductor structure according to an embodiment of the present disclosure.

### DETAILED DESCRIPTION OF THE EMBODIMENTS

Technical solutions in embodiments of the present disclosure are described clearly and completely below with reference to the drawings of the embodiments of the present disclosure. Apparently, the described embodiments are only a part, but not all of the embodiments of the present disclosure. All other embodiments that may be obtained by those of ordinary skill in the art based on the embodiments in the present disclosure without any inventive efforts fall into the protection scope of the present disclosure.

In order to improve a linearity of a high electron mobility transistor with a multi-channel heterostructure, the present disclosure provides a semiconductor structure and a manufacturing method therefor. The semiconductor structure includes a substrate, a buffer layer, a first channel layer, an etching mask layer, a first barrier layer, a second channel layer and a second barrier layer that are stacked sequentially. The etching mask layer includes a plurality of strip-shaped structures, a strip-shaped trench is formed between two adjacent strip-shaped structures in the plurality of strip-shaped structures, an extending direction of the strip-shaped trench is a first direction, the strip-shaped trench penetrates through the etching mask layer and partially penetrates through the first channel layer, the first barrier layer is conformally disposed in the strip-shaped trench and on the etching mask layer, and the first barrier layer includes a second trench corresponding to the strip-shaped trench. In the present disclosure, both longitudinal multi-channel and transverse multi-channel are designed, which improves a concentration of a two-dimensional electron gas, reduces a channel on-resistance, and concurrently achieves a relatively stable transconductance within a larger gate-source bias voltage range, improves a breakdown voltage, and improves dynamic characteristics, thereby improving a linearity of a device.

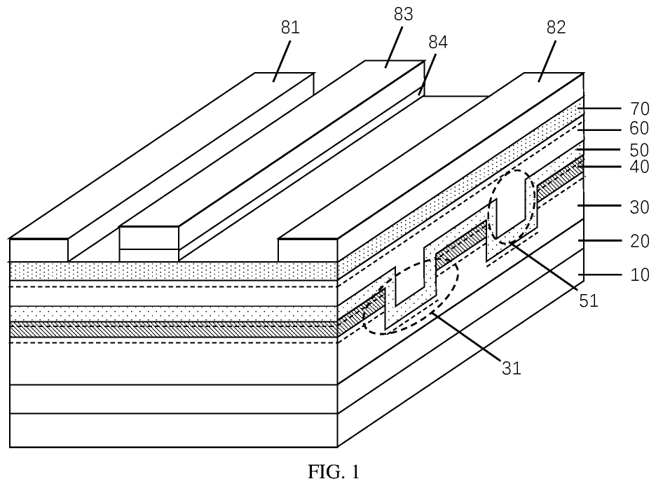

The semiconductor structure and the manufacturing method therefor mentioned in the present disclosure are further illustrated with examples below with reference to FIG. 1 to FIG. 12.

FIG. 1 is a schematic structural diagram of a semiconductor structure according to an embodiment of the present disclosure. As shown in FIG. 1, the semiconductor structure includes a substrate 10, a buffer layer 20, a first channel layer 30, an etching mask layer 40, a first barrier layer 50, a second channel layer 60 and a second barrier layer 70 that are stacked sequentially. The etching mask layer 40 includes a plurality of strip-shaped structures, a strip-shaped trench 31 is formed between two adjacent strip-shaped structures in the plurality of strip-shaped structures, an extension direction of the strip-shaped trench 31 is a first direction, and the strip-shaped trench 31 penetrates through the etching mask layer 40 and partially penetrates through the first channel layer 30. The first barrier layer 50 is conformally disposed in the strip-shaped trench 31 and on the etching mask layer 40, and the first barrier layer 50 includes a second trench 51 corresponding to the strip-shaped trench 31. The semiconductor structure of the present disclosure may be regarded as a parallel connection of a plurality of devices with different transconductance distributions, and through this parallel structure, a mutual compensation of different transconductance of a device is realized, thereby achieving a relatively stable transconductance value within a larger gate-source bias voltage range, so that the semiconductor structure has a good linearity.

Further, as shown in FIG. 1, the semiconductor structure further includes: a source 81 and a drain 82, located on the second barrier layer 70, where a direction of the source 81 pointing to the drain 82 is parallel to the first direction; a gate 83, located on the second barrier layer 70 and between the source 81 and the drain 82; and a dielectric layer 84, located on a side, close to the second barrier layer 70, of the gate 83. A material of the dielectric layer 84 includes at least one of aluminum oxide, aluminum nitride, and aluminum oxynitride. The material of the dielectric layer 84 has a strong ability to bind charges, and thus the charges are not easily polarized in a formed external electric field, and polarization charges are less, so that a polarization electric field is weak, thereby effectively avoiding a short-channel effect of the semiconductor structure. By disposing the dielectric layer 84, a Metal-Insulator-Semiconductor (MIS) gate structure is formed, which may effectively reduce a gate leakage current, and increase a gate voltage swing and a drain current swing, thereby further improving performance of the device.

In this embodiment, a band gap width of the first barrier layer 50 is greater than a band gap width of the etching mask layer 40, and the band gap width of the etching mask layer 40 is greater than a band gap width of the first channel layer 30. For example, in an embodiment, a material of the first barrier layer 50 includes AlN, a material of the etching mask layer 40 includes AlGaN, and a material of the first channel layer 30 includes GaN. Since the band gap width of the first barrier layer 50 is greater than that of the etching mask layer 40 and the band gap width of the etching mask layer 40 is greater than that of the first channel layer 30, a heterojunction interface of the first barrier layer 50 and the etching mask layer 40 may generate a two-dimensional electron gas, and a heterojunction interface of the etching mask layer 40 and the first channel layer 30 may also generate a two-dimensional electron gas, so that a concentration of a two-dimensional electron gas of the semiconductor structure may be improved, and a channel on-resistance may be reduced.

In an embodiment, at least one strip-shaped structure of the etching mask layer 40 has an Al component different from Al components of other strip-shaped structures of the etching mask layer 40. An improvement of Al component in the etching mask layer 40 may improve a density of the two-dimensional electron gas, thereby improving a saturation current of the device. By changing Al components at different positions in the etching mask layer 40, a saturation current at different positions of the semiconductor structure may be adjusted, and further, transconductance peaks of a heterojunction structure of the first barrier layer 50 and the etching mask layer 40 and a heterojunction structure of the etching mask layer 40 and the first channel layer 30 tend to be uniform. The semiconductor structure of the present disclosure may be regarded as a parallel connection of a plurality of devices with different transconductance distributions, and through this parallel structure, a mutual compensation of different transconductance of a device is realized, thereby achieving a relatively stable transconductance value within a larger gate-source bias voltage range, so that the semiconductor structure has a good linearity.

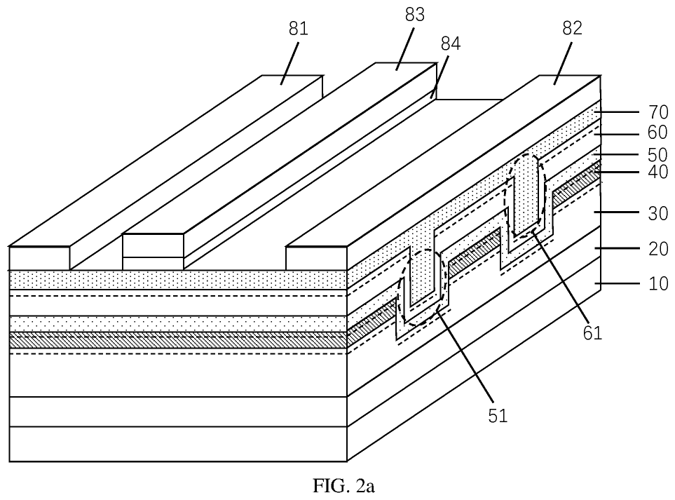

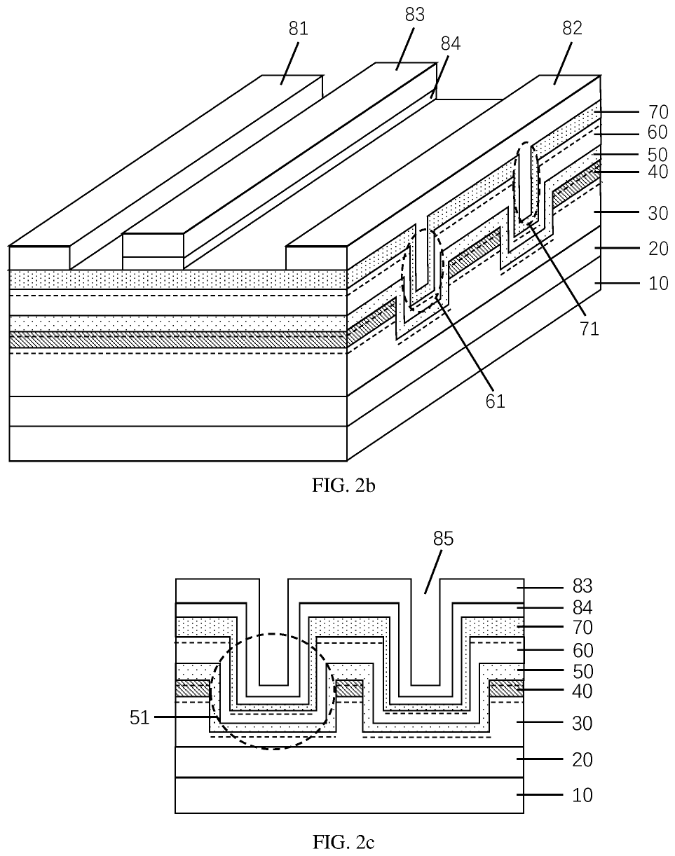

FIG. 2a to FIG. 2c are schematic structural diagrams of semiconductor structures according to some embodiments of the present disclosure. In an embodiment, as shown in FIG. 1, a surface, away from the first barrier layer 50, of the second channel layer 60 may be a plane, and a two-dimensional electron gas generated by a heterojunction interface between the second channel layer 60 and the second barrier layer 70 is located at a same horizontal plane. In another embodiment, as shown in FIG. 2a, the second channel layer 60 is conformally disposed on the first barrier layer 50, the second channel layer 60 includes a third trench 61 corresponding to the second trench 51, and a two-dimensional electron gas generated by a heterojunction interface between the second channel layer 60 and the second barrier layer 70 is not located at a same horizontal plane. In this way, a transverse multi-channel structure may be further formed, a mutual compensation of different transconductance of a device is facilitated, a transconductance within a larger gate-source bias voltage range is relatively stable, a breakdown voltage may be improved, and dynamic characteristics may be improved, thereby improving a linearity of a device. In yet another embodiment, as shown in FIG. 2b, while the second channel layer 60 is conformally disposed on the first barrier layer 50, the second barrier layer 70 is also conformally disposed on the second channel layer 60, the second barrier layer 70 includes a fourth trench 71 corresponding to the third trench 61, a two-dimensional electron gas generated by a heterojunction interface between the second channel layer 60 and the second barrier layer 70 is not located at a same horizontal plane, and the gate 83 fills the fourth trench 71 in the second barrier layer 70. In this way, in addition to an effect of further forming the transverse multi-channel structure, a control capability of the gate 83 on carriers is greatly improved, so that the breakdown voltage of a device may be greatly improved, a problem of leakage may be relieved, and efficiency and a linearity of a radio frequency device may be improved. In other embodiments, as shown in FIG. 2c, the second channel layer 60, the second barrier layer 70, the dielectric layer 84 and the gate 83 are conformally disposed on the first barrier layer 50 in sequence, and the gate 83 has a fifth trench 85 corresponding to the second trench 51, so that the control capability of the gate 83 on carriers may be further improved, and the linearity of the device may be further improved.

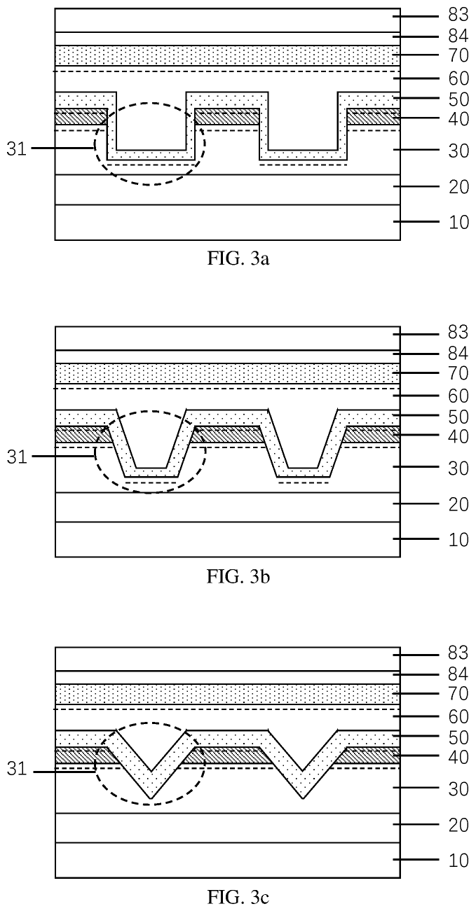

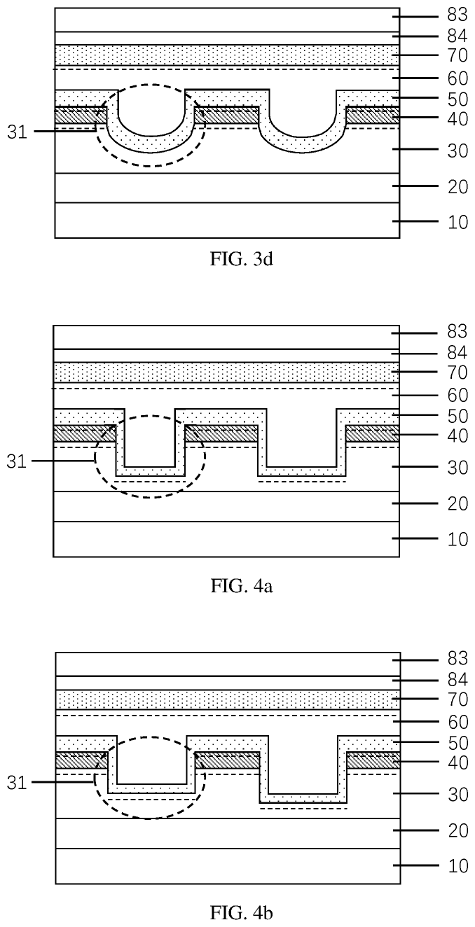

FIG. 3a to FIG. 3d are schematic structural diagrams of semiconductor structures according to some embodiments of the present disclosure. In an embodiment, in a plane perpendicular to the first direction, a cross section of the strip-shaped trench 31 is rectangular (as shown in FIG. 3a), trapezoidal (as shown in FIG. 3b), V-shaped (as shown in FIG. 3c) or bowl-shaped (as shown in FIG. 3d). A shape of the cross section of the strip-shaped trench 31 is not specifically limited in the present disclosure. A shape of the first barrier layer 50 in the strip-shaped trench 31 can be changed by changing a shape of the strip-shaped trench 31, so that a generated two-dimensional electron gas may be modulated, and a linearity of the semiconductor structure may be further improved.

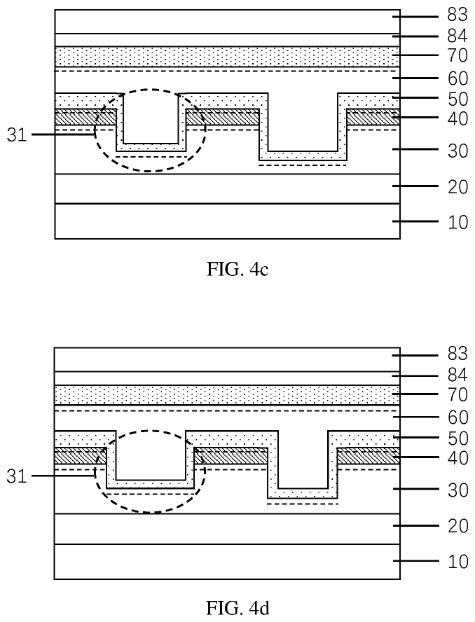

FIG. 4a to FIG. 4d are schematic structural diagrams of semiconductor structures according to some embodiments of the present disclosure. In an embodiment, at least one strip-shaped trench 31 has an aspect ratio different from aspect ratios of other strip-shaped trenches 31. As shown in FIG. 4a, a depth of the strip-shaped trenches 31 is constant and a width of the strip-shaped trenches 31 changes; or as shown in FIG. 4b, a depth of the strip-shaped trenches 31 changes and a width of the strip-shaped trenches 31 is constant; or as shown in FIG. 4c, a depth and a width of the strip-shaped trenches 31 change in a same proportion; or as shown in FIG. 4d, a depth and a width of the strip-shaped trenches 31 change in inverse proportions. By changing the depth and/or width of the strip-shaped trenches 31, a transconductance peak value of a heterojunction structure at different positions may be changed, a threshold voltage of the heterojunction structure at different positions may be changed, and a linear working characteristic of a device may be improved through a superposition of a plurality of heterojunction structures.

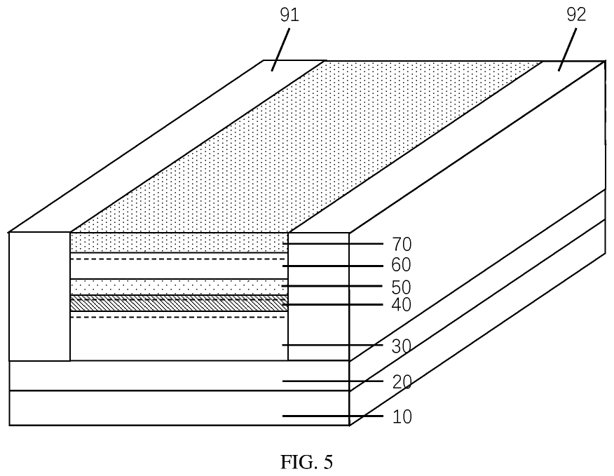

FIG. 5 is a schematic structural diagram of a semiconductor structure according to an embodiment of the present disclosure. In an embodiment, the semiconductor structure may be used to fabricate a diode, and as shown in FIG. 5, the semiconductor structure further includes: an anode 91 and a cathode 92, located on the buffer layer 20 and located on two sides of the first channel layer 30, the etching mask layer 40, the first barrier layer 50, the second channel layer 60 and the second barrier layer 70. A direction of the anode 91 pointing to the cathode 92 is parallel to the first direction. A diode device manufactured by a semiconductor structure of the present disclosure can also improve a breakdown voltage, improve dynamic characteristics, and improve a linearity of a device.

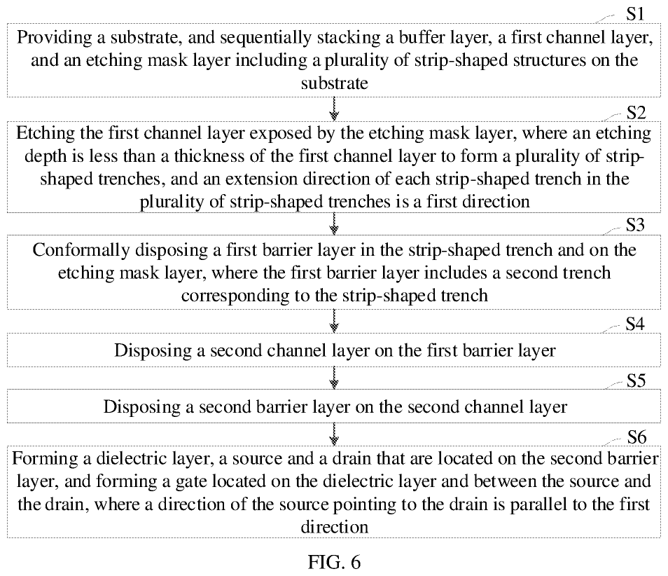

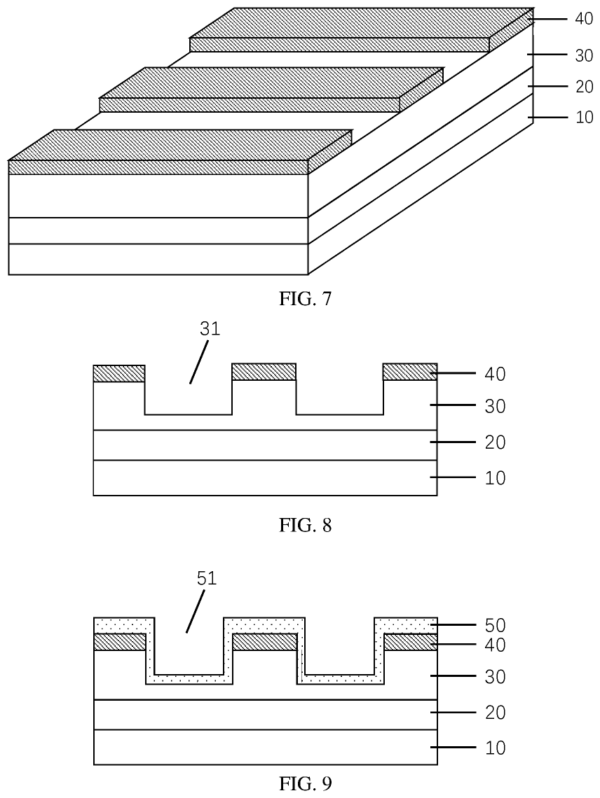

According to another aspect of the present disclosure, FIG. 6 is a flowchart of a manufacturing method for a semiconductor structure according to an embodiment of the present disclosure, and FIG. 7 to FIG. 12 are schematic structural diagrams of intermediate structures corresponding to a process for manufacturing a semiconductor structure according to an embodiment of the present disclosure. As shown in FIG. 6, a manufacturing method for a semiconductor structure according to an embodiment of the present disclosure may include the following steps.

Step S1: providing a substrate, and sequentially stacking a buffer layer, a first channel layer, and an etching mask layer including a plurality of strip-shaped structures on the substrate.

Specifically, as shown in FIG. 7, a material of the substrate 10 includes any one or a combination of more of Si, Al₂O₃, GaN, SiC, or AlN. A material of the buffer layer 20 is a group III nitride material, which may include one or more of GaN, AlGaN, and AlInGaN, and which is not limited thereto. A band gap width of the etching mask layer 40 is greater than a band gap width of the first channel layer 30, for example, a material of the etching mask layer 40 includes AlGaN, a material of the first channel layer 30 includes GaN, and a heterojunction interface between the etching mask layer 40 and the first channel layer 30 may generate a two-dimensional electron gas.

In this embodiment, a method for preparing the etching mask layer 40 including the plurality of strip-shaped structures may be: etching and removing a portion of the etching mask layer 40 by using a photolithography method after growing a film layer on an entire surface, to form the etching mask layer 40 including a plurality of strip-shaped structures. A method for preparing the etching mask layer 40 including the plurality of strip-shaped structures may also be: disposing a plurality of strip-shaped photoresist layers firstly, and then stripping the photoresist layers after growing a strip-shaped etching mask layer 40 between the photoresist layers. The method for preparing the etching mask layer 40 including the plurality of strip-shaped structures is not specifically limited in the present disclosure.

Step S2: etching the first channel layer exposed by the etching mask layer, where an etching depth is less than a thickness of the first channel layer to form a plurality of strip-shaped trenches, and an extension direction of each strip-shaped trench in the plurality of strip-shaped trenches is a first direction.

Specifically, as shown in FIG. 8, the first channel layer 30 exposed by the etching mask layer 40 is etched, an etching depth is less than a thickness of the first channel layer 30, a plurality of strip-shaped trenches 31 are formed, and an extension direction of the strip-shaped trench 31 is the first direction.

Step S3: conformally disposing a first barrier layer in the strip-shaped trench and on the etching mask layer, where the first barrier layer includes a second trench corresponding to the strip-shaped trench.

Specifically, as shown in FIG. 9, a first barrier layer 50 is conformally disposed in the strip-shaped trench 31 and on the etching mask layer 40, the first barrier layer 50 includes a second trench 51 corresponding to the strip-shaped trench 31, a band gap width of the first barrier layer 50 is greater than a band gap width of the etching mask layer 40, and a heterojunction interface between the first barrier layer 50 and the etching mask layer 40 may generate a two-dimensional electron gas.

Step S4: disposing a second channel layer on the first barrier layer.

Step S5: disposing a second barrier layer on the second channel layer.

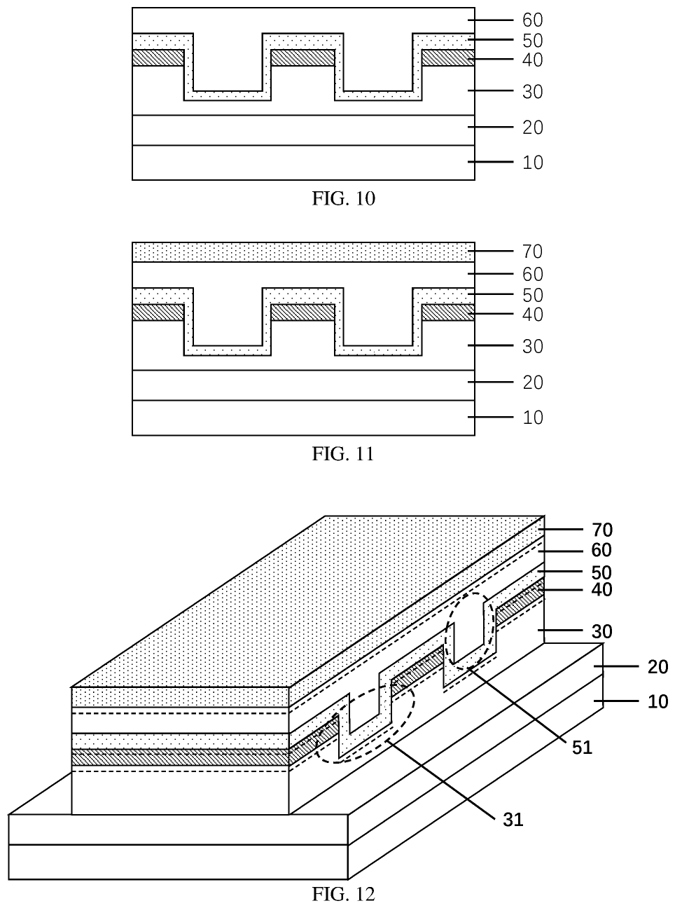

Specifically, as shown in FIG. 10, a second channel layer 60 is disposed on the first barrier layer 50. As shown in FIG. 11, a second barrier layer 70 is disposed on the second channel layer 60. A band gap width of the second barrier layer 70 is greater than a band gap width of the second channel layer 60, and a heterojunction interface between the second barrier layer 70 and the second channel layer 60 may generate a high-concentration two-dimensional electron gas.

Step S6: forming a dielectric layer, a source and a drain that are located on the second barrier layer, and forming a gate located on the dielectric layer and between the source and the drain, where a direction of the source pointing to the drain is parallel to the first direction.

Specifically, the dielectric layer 84, the source 81 and the drain 82 that are located on the second barrier layer 70, and the gate 83 located on the dielectric layer 84 and located between the source 81 and the drain 82 are formed, and a direction of the source 81 pointing to the drain 82 is parallel to the first direction, that is, the semiconductor structure shown in FIG. 1 is formed. A material of the dielectric layer 84 includes at least one of aluminum oxide, aluminum nitride, and aluminum oxynitride. The material of the dielectric layer 84 has a strong ability to bind charges, and thus the charges are not easily polarized in a formed external electric field, and polarization charges are less, so that a polarization electric field is weak, thereby effectively avoiding a short-channel effect of the semiconductor structure. By disposing the dielectric layer 84, an MIS gate structure is formed, which may effectively reduce a gate leakage current, and increase a gate voltage swing and a drain current swing, thereby further improving performance of the device.

In an embodiment, a grown second channel layer 60 completely fills the second trench 51 of the first barrier layer 50 and is flat, that is, a surface, away from the first barrier layer 50, of the second channel layer 60 is a plane, and as shown in FIG. 1, the two-dimensional electron gas generated by the heterojunction interface between the second channel layer 60 and the second barrier layer 70 is located at a same horizontal plane. In another embodiment, the grown second channel layer 60 may be conformally disposed on the first barrier layer 50, the second channel layer 60 includes a third trench 61 corresponding to the second trench 51, and as shown in FIG. 2a, the two-dimensional electron gas generated by the heterojunction interface between the second channel layer 60 and the second barrier layer 70 is not located at a same horizontal plane. In this way, a transverse multi-channel structure may be further formed, a mutual compensation of different transconductance of a device is facilitated, a transconductance within a larger gate-source bias voltage range is relatively stable, a breakdown voltage may be improved, and dynamic characteristics may be improved, thereby improving a linearity of a device. In yet another embodiment, as shown in FIG. 2b, while a grown second channel layer 60 is conformally disposed on the first barrier layer 50, a grown second barrier layer 70 is also conformally disposed on the second channel layer 60, the second barrier layer 70 includes a fourth trench 71 corresponding to the third trench 61, the gate 83 fills the fourth trench 71 in the second barrier layer 70, and the two-dimensional electron gas generated in the heterojunction interface between the second channel layer 60 and the second barrier layer 70 is not located at a same horizontal plane as well. In this way, in addition to an effect of further forming the transverse multi-channel structure, a control capability of the gate 83 on carriers is greatly improved, so that the breakdown voltage of a device may be greatly improved, a problem of leakage may be relieved, and efficiency and a linearity of a radio frequency device may be improved. In other embodiments, as shown in FIG. 2c, the second channel layer 60, the second barrier layer 70, the dielectric layer 84 and the gate 83 are conformally disposed on the first barrier layer 50 in sequence, and the gate 83 has a fifth trench 85 corresponding to the second trench 51, so that the control capability of the gate 83 on carriers may be further improved, and the linearity of the device may be further improved.

In an embodiment, in a plane perpendicular to the first direction, a cross section of the strip-shaped trench 31 is rectangular (as shown in FIG. 3a), trapezoidal (as shown in FIG. 3b), V-shaped (as shown in FIG. 3c) or bowl-shaped (as shown in FIG. 3d). A shape of the cross section of the strip-shaped trench 31 is not specifically limited in the present disclosure. A shape of the first barrier layer 50 in the strip-shaped trench 31 can be changed by changing a shape of the strip-shaped trench 31, so that a generated two-dimensional electron gas may be modulated, and a linearity of the semiconductor structure may be further improved.

In an embodiment, the strip-shaped trenches 31 formed by etching have different sizes, at least one strip-shaped trench 31 has an aspect ratio different from aspect ratios of other strip-shaped trenches 31. As shown in FIG. 4a, a depth of the strip-shaped trenches 31 is constant and a width of the strip-shaped trenches 31 changes; or as shown in FIG. 4b, a depth of the strip-shaped trenches 31 changes and a width of the strip-shaped trenches 31 is constant; or as shown in FIG. 4c, a depth and a width of the strip-shaped trenches 31 change in a same proportion; or as shown in FIG. 4d, a depth and a width of the strip-shaped trenches 31 change in inverse proportions. By changing the depth and/or width of the strip-shaped trenches 31, a transconductance peak value of a heterojunction structure subsequently grown at different positions may be changed, a threshold voltage of the heterojunction structure at different positions may be changed, and a linear working characteristic of a device may be improved through a superposition of a plurality of heterojunction structures.

In an embodiment, the semiconductor structure may be used to fabricate a diode, and after the Step S5, the manufacturing method for the semiconductor structure may further include the following step: etching the second barrier layer, the second channel layer, the first barrier layer, the etching mask layer and the first channel layer that are located at an anode region and a cathode region until the buffer layer is exposed, disposing an anode in the anode region, and disposing a cathode in the cathode region, where a direction of the anode pointing to the cathode is parallel to the first direction. Specifically, as shown in FIG. 12, the second barrier layer 70, the second channel layer 60, the first barrier layer 50, the etching mask layer 40 and the first channel layer 30 that are located at an anode region and a cathode region are etched until the buffer layer 20 is exposed, an anode 91 is disposed in the anode region, a cathode 92 is disposed in the cathode region, and a direction of the anode 91 pointing to the cathode 92 is parallel to the first direction, that is, a diode structure shown in FIG. 5 is formed. A diode device manufactured by a semiconductor structure of the present disclosure can also improve a breakdown voltage, improve dynamic characteristics, and improve a linearity of a device.

The present disclosure provides a semiconductor structure and a manufacturing method therefor. The semiconductor structure includes a substrate, a buffer layer, a first channel layer, an etching mask layer, a first barrier layer, a second channel layer and a second barrier layer that are stacked sequentially. The etching mask layer includes a plurality of strip-shaped structures, a strip-shaped trench is formed between two adjacent strip-shaped structures, an extending direction of the strip-shaped trench is a first direction, the strip-shaped trench penetrates through the etching mask layer and partially penetrates through the first channel layer, the first barrier layer is conformally disposed in the strip-shaped trench and on the etching mask layer, and the first barrier layer includes a second trench corresponding to the strip-shaped trench. In the present disclosure, both longitudinal multi-channel and transverse multi-channel are designed, which improves a concentration of a two-dimensional electron gas, reduces a channel on-resistance, and concurrently achieves a relatively stable transconductance within a larger gate-source bias voltage range, improves a breakdown voltage, and improves dynamic characteristics, thereby improving a linearity of a device.

In the present disclosure, a plurality of strip-shaped trenches are designed in the first channel layer, and a heterogeneous interface between the first barrier layer located at a side wall of the strip-shaped trench and the first channel layer is substantially parallel to a direction of a polarization axis. There is basically no polarization effect, and no carrier generation, so that a two-dimensional electron gas in the first channel layer may be limited to a bottom surface of a trench and to a top surface between adjacent trenches, which enables a two-dimensional electron gas in a heterojunction structure to present an approximate one-dimensional transportation mode during a migration process, and may improve a carrier mobility. Meanwhile, a design of the transverse multi-channel is equivalent to that a plurality of heterojunction structures are connected in parallel between a source and a drain, and compared with a planar heterojunction structure device, a mutual compensation of different transconductance of a device is facilitated, a transconductance within a larger gate-source bias voltage range is relatively stable, a breakdown voltage may be improved, and dynamic characteristics may be improved, thereby improving a linearity of a device.

A heterogeneous interface between the second channel layer and the second barrier layer of the present disclosure can generate a two-dimensional electron gas with a high concentration and a high mobility, a heterogeneous interface between the first channel layer and the etching mask layer, a heterogeneous interface between the etching mask layer and the first barrier layer, and the heterogeneous interface between the first channel layer and the first barrier layer can supplement carriers, further improve the concentration of the two-dimensional electron gas, and reduce the channel on-resistance. Based on a design of the longitudinal multi-channel, while the concentration of the two-dimensional electron gas and the carrier mobility are improved, electric field lines may be dispersed, and an electric field intensity is weakened, so that a breakdown voltage of the semiconductor structure is improved.

It should be understood that the terms “including” and its modification used in this disclosure are open-ended, that is, “including but not limited to”. The term “an embodiment” represents “at least one embodiment”; and the term “another embodiment” means “at least one another embodiment”. In this specification, a schematic description of foregoing terms does not have to be directed to a same embodiment or example. Further, specific features, structures, materials, or features described may be incorporated in an appropriate manner in any one or more embodiments or examples. In addition, without being contradictory, a person skilled in the art may combine and permutate different embodiments or examples described in this specification and features of different embodiments or examples.

The foregoing descriptions are merely exemplary embodiments of the present disclosure, and are not intended to limit the present disclosure. Any modification, an equivalent replacement, or the like made within a spirit and principles of the present disclosure shall be included in a protection scope of the present disclosure.

What is claimed is:

1. A semiconductor structure, comprising:
a substrate, a buffer layer, a first channel layer, an etching mask layer, a first barrier layer, a second channel layer and a second barrier layer that are stacked sequentially,
wherein the etching mask layer comprises a plurality of strip-shaped structures, a strip-shaped trench is formed between two adjacent strip-shaped structures in the plurality of strip-shaped structures, an extension direction of the strip-shaped trench is a first direction, the strip-shaped trench penetrates through the etching mask layer and partially penetrates through the first channel layer, the first barrier layer is conformally disposed in the strip-shaped trench and on the etching mask layer, and the first barrier layer comprises a second trench corresponding to the strip-shaped trench.

2. The semiconductor structure according to claim 1, wherein a band gap width of the first barrier layer is greater than a band gap width of the etching mask layer, and the band gap width of the etching mask layer is greater than a band gap width of the first channel layer.

3. The semiconductor structure according to claim 2, wherein a material of the first barrier layer comprises AlN, a material of the etching mask layer comprises AlGaN, and a material of the first channel layer comprises GaN.

4. The semiconductor structure according to claim 3, wherein an Al component of at least one strip-shaped structure in the plurality of strip-shaped structures is different from an Al component of a remaining strip-shaped structure in the plurality of strip-shaped structures.

5. The semiconductor structure according to claim 1, wherein a surface, away from the first barrier layer, of the second channel layer is a plane.

6. The semiconductor structure according to claim 1, wherein the second channel layer is conformally disposed on the first barrier layer, and the second channel layer comprises a third trench corresponding to the second trench.

7. The semiconductor structure according to claim 6, wherein the second barrier layer is conformally disposed on the second channel layer, and the second barrier layer comprises a fourth trench corresponding to the third trench.

8. The semiconductor structure according to claim 1, wherein in a plane perpendicular to the first direction, a cross section of the strip-shaped trench is rectangular, trapezoidal, V-shaped, or bowl-shaped.

9. The semiconductor structure according to claim 1, wherein a plurality of strip-shaped trenches are formed between the plurality of strip-shaped structures, and an aspect ratio of at least one strip-shaped trench in the plurality of strip-shaped trenches is different from an aspect ratio of a remaining strip-shaped trench in the plurality of strip-shaped trenches.

10. The semiconductor structure according to claim 9, wherein a change trend of an aspect ratio of the plurality of strip-shaped trenches comprises any one of the following change trends:
a depth of the plurality of strip-shaped trenches is constant and a width of the plurality of strip-shaped trenches changes;
a depth of the plurality of strip-shaped trenches changes and a width of the plurality of strip-shaped trenches is constant;
a depth and a width of the plurality of strip-shaped trenches change in a same proportion; and
a depth and a width of the plurality of strip-shaped trenches change in inverse proportions.

11. The semiconductor structure according to claim 1, further comprising:
a source and a drain, located on the second barrier layer, wherein a direction of the source pointing to the drain is parallel to the first direction;
a gate, located on the second barrier layer and between the source and the drain; and
a dielectric layer, located on a side, close to the second barrier layer, of the gate.

12. The semiconductor structure according to claim 11, wherein the second channel layer, the second barrier layer, the dielectric layer and the gate are conformally disposed on the first barrier layer in sequence, and the gate has a fifth trench corresponding to the second trench.

13. The semiconductor structure according to claim 1, further comprising:
an anode and a cathode, located on the buffer layer and located on two sides of the first channel layer, the etching mask layer, the first barrier layer, the second channel layer and the second barrier layer, wherein a direction of the anode pointing to the cathode is parallel to the first direction.

14. A manufacturing method for a semiconductor structure, comprising:
sequentially stacking a buffer layer, a first channel layer, and an etching mask layer comprising a plurality of strip-shaped structures on a substrate;
etching the first channel layer exposed by the etching mask layer, wherein an etching depth is less than a thickness of the first channel layer to form a plurality of strip-shaped trenches, and an extension direction of each strip-shaped trench in the plurality of strip-shaped trenches is a first direction;
conformally disposing a first barrier layer in the strip-shaped trench and on the etching mask layer, wherein the first barrier layer comprises a second trench corresponding to the strip-shaped trench;
disposing a second channel layer on the first barrier layer; and
disposing a second barrier layer on the second channel layer.

15. The manufacturing method for the semiconductor structure according to claim 14, wherein a surface, away from the first barrier layer, of the second channel layer is a plane.

16. The manufacturing method for the semiconductor structure according to claim 14, wherein the second channel layer is conformally disposed on the first barrier layer, and the second channel layer comprises a third trench corresponding to the second trench.

17. The manufacturing method for the semiconductor structure according to claim 16, wherein the second barrier layer is conformally disposed on the second channel layer, and the second barrier layer comprises a fourth trench corresponding to the third trench.

18. The manufacturing method for the semiconductor structure according to claim 14, wherein in a plane perpendicular to the first direction, a cross section of the strip-shaped trench is rectangular, trapezoidal, V-shaped, or bowl-shaped.

19. The manufacturing method for the semiconductor structure according to claim 14, wherein an aspect ratio of at least one strip-shaped trench in the plurality of strip-shaped trenches is different from an aspect ratio of a remaining strip-shaped trench in the plurality of strip-shaped trenches.

20. The manufacturing method for the semiconductor structure according to claim 14, further comprising:
forming a dielectric layer, a source and a drain that are located on the second barrier layer, and forming a gate located on the dielectric layer and between the source and the drain, wherein a direction of the source pointing to the drain is parallel to the first direction.
